(19) United States
(12) Patent Application Publication
(10) Pub. No.: US 2026/0123106 A1
(43) Pub. Date: Apr. 30, 2026

(54) LIGHT EMITTING APPARATUS AND MODULE HAVING THE SAME

(71) Applicant: SEOUL VIOSYS CO., LTD., Ansan-si (KR)

(72) Inventors: Miso KO, Ansan-si (KR); Eunmi CHOI, Ansan-si (KR)

(73) Assignee: SEOUL VIOSYS CO., LTD., Ansan-si (KR)

(21) Appl. No.: 19/366,753

(22) Filed: Oct. 23, 2025

Related U.S. Application Data
(60) Provisional application No. 63/711,765, filed on Oct. 25, 2024.

(51) Int. Cl. H10H 20/819; H10H 20/812; H10H 20/831; H10H 20/84; H10H 29/14; H10H 29/80; H10H 29/85; H10H 29/853

(52) U.S. Cl. CPC H10H 20/819; H10H 20/812; H10H 20/8314; H10H 20/84; H10H 29/142; H10H 29/8321; H10H 29/842; H10H 29/853; H10H 29/857

(57) ABSTRACT

The present disclosure discloses a light emitting apparatus that includes a semiconductor layer, a support layer supporting the semiconductor layer, a first electrode disposed between the support layer and the semiconductor layer, and a second electrode disposed on the semiconductor layer, in which the semiconductor layer includes a first conductivity type semiconductor layer disposed on the first electrode and electrically connected to the first electrode, an active layer covering the first conductivity type semiconductor layer, and a second conductivity type semiconductor layer covering the active layer and electrically connected to the second electrode, and a cross-sectional length of a first surface of the first conductivity type semiconductor layer facing the first electrode is shorter than a cross-sectional length of a second surface facing the active layer.

### TECHNICAL FIELD

The present disclosure relates to a light emitting apparatus and a light emitting module having the same.

### BACKGROUND ART

A light emitting diode (LED) is one of the light emitting devices that emit light when current is applied. Recently, the light emitting diode has been widely used in various technical fields such as display apparatuses, vehicle lamps, and general lighting. Moreover, the light emitting diode has advantages of long life, low power consumption, and fast response speed. By taking full advantage of these characteristics, light emitting diodes are rapidly replacing conventional light sources. For example, a display apparatus using the light emitting diode may be obtained by forming structures of individually grown red R, green G, and blue B light emitting diodes (LEDs) on a final substrate.

In detail, the light emitting diode is formed by growing epitaxial layers on a substrate, and includes an n-type semiconductor layer, a p-type semiconductor layer, and an active layer interposed therebetween. An n-electrode pad is formed on the n-type semiconductor layer, and a p-electrode pad is formed on the p-type semiconductor layer, so that the light emitting diode is driven by being electrically connected to an external power source through the electrode pads. In this case, current can flow from the p-electrode pad through the semiconductor layers to the n-electrode pad, and light generated through the recombination of electrons and holes in the active layer may be emitted.

### DISCLOSURE

### Technical Problem

The present disclosure is to provide a light emitting apparatus and a light emitting module having the same that suppress local heat generation and improve light emission efficiency by optimizing thicknesses and cross-sectional shapes of a first conductivity type semiconductor layer, an active layer, and a second conductivity type semiconductor layer of a light emitting device to improve a flow and a spreading path of current.

The present disclosure is to provide a light emitting apparatus and a light emitting module having the same that induce current to be distributed more uniformly across the entire active layer, stabilize a flow of current, and improve light emission efficiency and reliability by designing a cross-sectional length of a first surface of a first conductivity type semiconductor layer facing a first electrode to be shorter than a cross-sectional length of a second surface facing the active layer.

The present disclosure is to provide a light emitting apparatus and a light emitting module having the same that prevent a problem of current being crowded in a specific region and improve current spreading by forming a center portion and an outer portion of a first conductivity type semiconductor layer having different thicknesses.

The present disclosure is to provide a light emitting apparatus and a light emitting module having the same that expand the emission wavelength distribution and improve color uniformity by forming a difference in thickness and a difference in indium (In) composition between a center portion and an outer portion within an active layer.

The present disclosure aims to provide a light emitting apparatus and a light emitting module having the same that expand a current spreading path and increase light emission efficiency by increasing a cross-sectional length of a surface of a second conductivity type semiconductor layer.

The present disclosure aims to provide a light emitting apparatus and a light emitting module having the same that induce uniform injection of current and implement stable light emitting characteristics throughout a light emitting region by designing a width of an opening formed in an insulation layer over a second conductivity type semiconductor layer to be smaller than a cross-sectional length of a first conductivity type semiconductor layer.

The present disclosure aims to provide a light emitting apparatus and a light emitting module having the same that improve light emitting characteristics, light output, and light emitting uniformity through precisely controlling resistance distribution and current flow by designing a first conductivity type semiconductor layer in various cross-sectional shapes, such as an arc or a trapezoid.

### Technical Solution

A light emitting apparatus according to an embodiment of the present disclosure may include a semiconductor layer, a support layer supporting the semiconductor layer, a first electrode disposed between the support layer and the semiconductor layer, and a second electrode disposed on the semiconductor layer.

In an embodiment, the semiconductor layer may include a first conductivity type semiconductor layer disposed on the first electrode and electrically connected to the first electrode, an active layer covering the first conductivity type semiconductor layer, and a second conductivity type semiconductor layer covering the active layer and electrically connected to the second electrode.

In an embodiment, a cross-sectional length of a first surface facing the first electrode of the first conductivity type semiconductor layer may be shorter than a cross-sectional length of a second surface facing the active layer.

In an embodiment, the light emitting apparatus may further include a second insulation layer covering the second conductivity type semiconductor layer and provided with an opening for connecting the second conductivity type semiconductor layer and the second electrode.

In an embodiment, a width of the opening in cross-sectional view may be smaller than the cross-sectional length of the first surface.

In an embodiment, the light emitting apparatus may further include a first insulation layer disposed on the support layer and surrounding the first conductivity type semiconductor layer.

In an embodiment, a thickness of the first conductivity type semiconductor layer at a center in cross-sectional view may be different from a thickness of the first conductivity type semiconductor layer at an outer periphery.

In an embodiment, the thickness of the first conductivity type semiconductor layer may be maximum at the center.

In an embodiment, the first conductivity type semiconductor layer may have an arc cross-sectional shape.

In an embodiment, an angle formed by two line segments connecting a vertex of the first conductivity type semiconductor layer and each of two edges in a lower portion of the first conductivity type semiconductor layer in cross-sectional view may be an obtuse angle.

In an embodiment, a vertical length of the first conductivity type semiconductor layer from a center in the lower portion of the first conductivity type semiconductor layer in cross-sectional view may be shorter than a length from the center in the lower portion to the edge in the lower portion.

In an embodiment, a length of a surface of the second conductivity type semiconductor layer in cross-sectional view may be longer than a length of the second surface.

In an embodiment, a thickness of the second conductivity type semiconductor layer at a center in cross-sectional view may be different from a thickness of the second conductivity type semiconductor layer at an outer periphery.

In an embodiment, a thickness of the active layer at a center in cross-sectional view may be different from a thickness of the active layer at an outer periphery.

In an embodiment, the active layer includes a multi-quantum well structure (MQW) including a plurality of barrier layers and a plurality of well layers, and an indium content of the well layer at the center in cross-sectional view may be different from an indium content of the well layer at the outer periphery.

In an embodiment, a color of light emitted from the active layer at the center in cross-sectional view may be different from a color of light emitted at the outer periphery.

In an embodiment, the first conductivity type semiconductor layer may have a trapezoidal cross-sectional shape.

A light emitting apparatus according to an embodiment of the present disclosure may include a semiconductor layer, a support layer supporting the semiconductor layer, a second electrode disposed between the support layer and the semiconductor layer, and a first electrode disposed on the semiconductor layer.

In an embodiment, the semiconductor layer may include a second conductivity type semiconductor layer disposed on the second electrode and electrically connected to the second electrode, an active layer disposed on the second conductivity type semiconductor layer, and a first conductivity type semiconductor layer disposed on the active layer.

In an embodiment, a cross-sectional length of a first surface facing the first electrode of the first conductivity type semiconductor layer may be shorter than a cross-sectional length of a second surface facing the active layer.

In an embodiment, a first insulation layer covering the first conductivity type semiconductor layer and having an opening OP for connecting the first conductivity type semiconductor layer and the first electrode may be further included.

In an embodiment, the second conductivity type semiconductor layer may be a semiconductor layer doped with a p-type dopant, and a width of the second conductivity type semiconductor layer in cross-sectional view may be longer than a width of the first conductivity type semiconductor layer.

In an embodiment, a width of the first conductivity type semiconductor layer in cross-sectional view may decrease in a direction away from the active layer.

In an embodiment, the semiconductor layer may be provided in a plurality and be spaced apart from one another in plan view, and a cover layer covering the plurality of semiconductor layers may be further included.

In an embodiment, the cover layer may include a plurality of protrusions formed corresponding to each of the plurality of semiconductor layers.

### ADVANTAGEOUS EFFECT

The present disclosure may provide a light emitting apparatus and a light emitting module having the same that suppress local heat generation and improve light emission efficiency by optimizing thicknesses and cross-sectional shapes of a first conductivity type semiconductor layer, an active layer, and a second conductivity type semiconductor layer of a light emitting device to improve a flow and a spreading path of current.

The present disclosure may provide a light emitting apparatus and a light emitting module having the same that induce current to be distributed more uniformly across the entire active layer, stabilize a flow of current, and improve light emission efficiency and reliability by designing a cross-sectional length of a first surface of a first conductivity type semiconductor layer facing a first electrode to be shorter than a cross-sectional length of a second surface facing the active layer.

The present disclosure may provide a light emitting apparatus and a light emitting module having the same that prevent a problem of current being crowded in a specific region and improve current spreading by forming a center portion and an outer portion of a first conductivity type semiconductor layer having different thicknesses.

The present disclosure may provide a light emitting apparatus and a light emitting module having the same that expand the emission wavelength distribution and improve color uniformity by forming a difference in thickness and a difference in indium (In) composition between a center portion and an outer portion within an active layer.

The present disclosure may provide a light emitting apparatus and a light emitting module having the same that is configured to expand a current spreading path and increase light emission efficiency by increasing a cross-sectional length of a surface of a second conductivity type semiconductor layer.

The present disclosure may provide a light emitting apparatus and a light emitting module having the same that induce uniform injection of current and implement stable light emitting characteristics throughout a light emitting region by designing a width of an opening formed in an insulation layer over a second conductivity type semiconductor layer to be smaller than a cross-sectional length of a first conductivity type semiconductor layer.

The present disclosure may provide a light emitting apparatus and a light emitting module having the same that improve light emitting characteristics, light output, and light emitting uniformity through precisely controlling resistance distribution and current flow by designing a first conductivity type semiconductor layer in various cross-sectional shapes, such as an arc or a trapezoid.

### BRIEF DESCRIPTION OF DRAWING

FIG. 1 is a cross-sectional view of a light emitting apparatus according to an embodiment of the present disclosure.

FIG. 2 is an enlarged view showing an active layer of FIG. 1.

FIG. 3 is a cross-sectional view of a light emitting apparatus according to another embodiment of the present disclosure.

FIG. 4 is a plan view of a light emitting apparatus according to another embodiment of the present disclosure.

FIG. 5 is a cross-sectional view in a direction of I-I′ of FIG. 4.

FIG. 6 is a cross-sectional view in a direction of II-II′ of FIG. 4.

### DETAILED DESCRIPTION OF THE ILLUSTRATED EMBODIMENTS

In the following description, for the purposes of explanation, numerous specific details are set forth in order to provide thorough understanding of various exemplary embodiments or implementations of the present disclosure. As used herein, “embodiments” and “implementations” are interchangeable terms for non-limiting examples of devices or methods employing one or more of the inventive concepts disclosed herein. It will be apparent, however, that various exemplary embodiments may be practiced without these specific details or with one or more equivalent arrangements. In other instances, well-known structures and devices are shown in block diagram form in order to avoid unnecessarily obscuring various exemplary embodiments. Further, various exemplary embodiments may be different, but do not have to be exclusive. For example, specific shapes, configurations, and characteristics of an exemplary embodiment may be used or implemented in another exemplary embodiment without departing from the inventive concepts.

Unless otherwise specified, the illustrated exemplary embodiments are to be understood as providing exemplary features of varying detail of some ways in which the inventive concepts may be implemented in practice. Therefore, unless otherwise specified, the features, components, modules, layers, films, panels, regions, and/or aspects (hereinafter individually or collectively referred to as “elements”) of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, and property of the elements, unless specified. Further, in the accompanying drawings, the size and relative sizes of elements may be exaggerated for clarity and/or descriptive purposes. When an exemplary embodiment is implemented differently, a specific process order may be performed differently from the described order. For example, two consecutively described processes may be performed substantially at the same time or performed in an order opposite the described order. In addition, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the x, y, and z-axes, and may be interpreted in a broader sense. For example, the DR1-axis, the DR2-axis, and the DR3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (for example, as in “sidewall”), and the like, may be used herein for descriptive purposes, and, thereby, to describe one element's relationship to other element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (for example, rotated 90 degrees or at other orientations), and, as such, the spatially relative descriptors used herein may likewise interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various exemplary embodiments are described herein with reference to sectional and/or exploded illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some exemplary embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (for example, microcode) to perform various functions discussed herein and may optionally be driven by firmware and/or software. It is also contemplated that each block, unit, and/or module may be implemented by dedicated hardware, or as a combination of dedicated hardware to perform some functions and a processor (for example, one or more programmed microprocessors and associated circuitry) to perform other functions. Also, each block, unit, and/or module of some exemplary embodiments may be physically separated into two or more interacting and discrete blocks, units, and/or modules without departing from the scope of the inventive concepts. Further, the blocks, units, and/or modules of some exemplary embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure pertains. Terms, such as those defined in commonly used dictionaries, should be interpreted as having a meaning that is consistent with their meaning in the context of the relevant art and should not be interpreted in an idealized or overly formal sense, unless expressly so defined herein.

Hereinafter, a light emitting apparatus of the present disclosure and a light emitting module having the same will be described in detail through accompanying drawings.

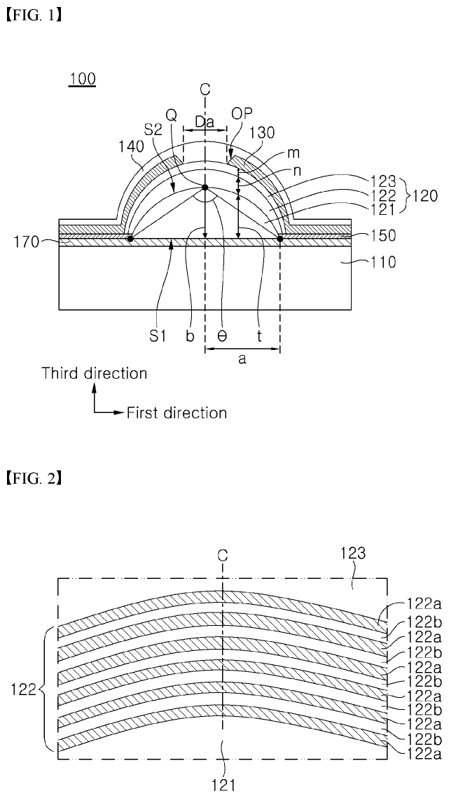

Referring to FIG. 1, a light emitting apparatus 100 according to an embodiment of the present disclosure may include a semiconductor layer 120 and a support layer 110 supporting the semiconductor layer 120. Furthermore, it may further include a first electrode 170 disposed between the support layer 110 and the semiconductor layer, and a second electrode 140 disposed on the semiconductor layer 120.

The support layer 110 is a base for supporting the semiconductor layer 120 and is not limited to a specific type, material, or structure. For example, the support layer 110 may be a support substrate, such as a circuit board, a light-transmitting substrate, a glass substrate, a TFT substrate, a polymer substrate, a flexible substrate, a polyimide substrate, or others. The support layer 110 may be selected according to an application purpose or manufacturing process of the light emitting apparatus 100, and in particular, in a case that a flexible substrate or polyimide substrate is used, it may provide a structure suitable for a flexible display or wearable apparatus.

The support layer 110 may be formed with an area larger than that of the semiconductor layer 120. The support layer 110 may support a plurality of light emitting devices, or may provide a region for forming interconnections or electrodes. The support layer 110 may have a single-layer structure, or may have a multi-layer structure in which a plurality of layers having different physical characteristics are stacked. The support layer 110 may improve a reliability of the light emitting apparatus 100 by including a material with high thermal conductivity or a material with high mechanical strength.

The semiconductor layer 120 may include a first conductivity type semiconductor layer 121 disposed over the support layer 110, an active layer 122 covering the first conductivity type semiconductor layer 121, and a second conductivity type semiconductor layer 123 covering the active layer 122.

The first conductivity type semiconductor layer 121 may include a phosphide or nitride semiconductor such as (Al, Ga, In)P or (Al, Ga, In)N. The first conductivity type semiconductor layer 121 may be grown using a technique such as MOCVD, MBE, HVPE, or others.

The first conductivity type semiconductor layer 121 may be doped as n-type by including one or more types of impurities such as Si, C, Ge, Sn, Te, Pb, or others. However, the inventive concepts are not limited thereto, and the first conductivity type semiconductor layer 121 may be doped with an opposite conductivity type, including a p-type dopant.

The active layer 122 may be a light emitting layer disposed on a side of the first conductivity type semiconductor layer 121. The active layer 122 is a light emitting layer formed on a side of the first conductivity type semiconductor layer 121, which may include a phosphide or nitride semiconductor such as (Al, Ga, In)P or (Al, Ga, In)N, and may be grown on the first conductivity type semiconductor layer 121 using a technique such as MOCVD, MBE, HVPE, or the like. In addition, the active layer 122 may include a quantum well structure (QW) including at least two barrier layers 122a and at least one well layer 122b, and furthermore, may include a multi-quantum well structure (MQW) including a plurality of barrier layers 122a and a plurality of well layers 122b. A wavelength of light emitted from the active layer 122 may be adjusted by controlling a composition ratio of materials forming the well layer 122b.

The second conductivity type semiconductor layer 123 may be a semiconductor layer disposed on a side of the active layer 122. The second conductivity type semiconductor layer 123 may include a phosphide or nitride semiconductor such as (Al, Ga, In)P or (Al, Ga, In)N, and may be grown using a technique such as MOCVD, MBE, HVPE, or the like. The second conductivity type semiconductor layer 123 may be doped with a conductivity type opposite to that of the first conductivity type semiconductor layer 121. For example, the second conductivity type semiconductor layer 123 may be doped as a p-type by including an impurity such as Mg.

The first electrode 170 is an electrode disposed between the support layer 110 and the first conductivity type semiconductor layer 121, and the first conductivity type semiconductor layer 121 may be electrically connected to the first electrode 170.

The first electrode 170 may be disposed on a lower surface of the first conductivity type semiconductor layer 121 and connected to an external power source. The lower surface of the first conductivity type semiconductor layer 121 is a surface facing the first electrode and may be a first surface S1 of the first conductivity type semiconductor layer 121.

The first electrode 170 may form an ohmic contact with the first conductivity type semiconductor layer 121 to enable smooth injection of electrons. The first electrode 170 may be a metal having high electrical conductivity and stable bonding characteristics with the first conductivity type semiconductor layer 121, and may be, for example, a single metal such as titanium (Ti), aluminum (Al), nickel (Ni), gold (Au), silver (Ag), platinum (Pt), molybdenum (Mo), chromium (Cr), or others, or an alloy or stacked structure thereof. In addition, a transparent conductive oxide (ITO, IZO, or others) may be further included for improving characteristics of semiconductor-metal bonding, or light extraction efficiency may be increased by including a reflection film.

The second electrode 140 is an electrode disposed on the semiconductor layer 120, and the second conductivity type semiconductor layer 123 may be electrically connected to the second electrode 140.

The second electrode 140 may cover the second conductivity type semiconductor layer 123. The second electrode 140 may be formed to cover all or a portion of the second conductivity type semiconductor layer 123, and may have a mesh structure, a transparent electrode structure, or a reflective electrode structure to ensure uniformity of current distribution.

The second electrode 140 may also be a metallic material with high electrical conductivity, and may be a single metal such as aluminum (Al), silver (Ag), gold (Au), nickel (Ni), or others, or a multilayer film thereof. Alternatively, the second electrode 140 may be applied with a transparent electrode material such as a transparent conductive oxide (ITO, ZnO, IZO, or others), graphene, or carbon nanotube (CNT) to increase light emission efficiency.

In addition, the second electrode 140 may include a reflection film structure that adjusts a reflectivity of the electrode to increase light extraction efficiency, and may optimize current spreading characteristics through surface roughness control or micropatterning.

Referring back to FIG. 1, when the lower surface of the first conductivity type semiconductor layer 121 in cross-sectional view is the first surface S1 facing the first electrode 170, an upper surface of the first conductivity type semiconductor layer 121 facing the active layer 122 may be a second surface S2.

Due to a cross-sectional shape of the first conductivity type semiconductor layer 121 and a structure in which the active layer 122 covers the first conductivity type semiconductor layer 122, a cross-sectional length of the first surface S1 may be shorter than a cross-sectional length of the second surface S2. In other words, the cross-sectional length of the second surface S2 may be formed longer than the cross-sectional length of the first surface S1.

As the cross-sectional length of the first surface S1 is formed narrow, when electrons are injected from an external power source, electrons may naturally spread within the first conductivity type semiconductor layer 121 and transferred to a second surface S2 side facing the active layer 122. Accordingly, a phenomenon of electrons being crowded in a specific region may be suppressed, and electrons may be uniformly distributed throughout the active layer 122 in contact with the second surface S2 side.

In addition, in a process which electrons injected from the first surface S1 spread to the second surface S2, an electron movement path may be lengthened and dispersed, thereby increasing a current spreading effect. Accordingly, a recombination of electrons and holes may occur efficiently in an entire region of the active layer 122, and light emission efficiency may be improved. In addition, a phenomenon of electron flow being crowded in the specific region may be reduced, so that local heat generation may be suppressed, and accordingly, a thermal stability of the light emitting apparatus 100 may be increased, and an operation reliability thereof may be improved.

In addition, since electrons are uniformly injected into the entire the active layer 122, a light emitting wavelength may be stably maintained within the multi-quantum well (MQW) structure, and color uniformity may be improved.

Thicknesses t of the first conductivity type semiconductor layer 121 in cross-sectional view may be different at a center and an outer periphery. A thickness t of the first conductivity type semiconductor layer 121 at the center in cross-sectional view may be different from a thickness t of the first conductivity type semiconductor layer 121 at the outer periphery. For example, the thickness t of the first conductivity type semiconductor layer 121 may be larger at the center than at the outer periphery.

In addition, the thickness of the first conductivity type semiconductor layer 121 may be maximum at the center in cross-sectional view. That is, when an imaginary center line passing through a center of the semiconductor layer 120 is C, the thickness t of the first conductivity type semiconductor layer 121 may have a maximum value b at the center line C. The B may be a vertical distance from a point Q intersecting the center line C of the second surface S2 of the first conductivity type semiconductor layer 121 to the first surface S1 positioned vertically below the Q. The point Q may be a vertex of the first conductivity type semiconductor layer 121.

The first conductivity type semiconductor layer 121 may have various cross-sectional shapes, and the inventive concepts are not limited to a specific shape. For example, the first conductivity type semiconductor layer 121 may have an arc cross-sectional shape. Alternatively, the first conductivity type semiconductor layer 121 may be formed as a trapezoid, a multi-curved surface having a plurality of radii of curvature, or an asymmetrical surface that is not centrally symmetric.

In this case, an angle 0 formed by two line segments connecting the vertex Q of the first conductivity type semiconductor layer 121 and each of two edges (edges of the first surface S1) in a lower portion of the first conductivity type semiconductor layer 121 in cross-sectional view may be an obtuse angle.

In addition, a vertical length b of the first conductivity type semiconductor layer 121 from a center in the lower portion of the first conductivity type semiconductor layer 121 in cross-sectional view may be shorter than a length a from the center in the lower portion to the edge in the lower portion. In other words, the length a between the center line C and the edge of the first surface S1 may be longer than the thickness b of the first conductivity type semiconductor layer 121 at the center line C.

The shape of the first conductivity type semiconductor layer 121 that is gently open out like this prevents electrons from being crowded in a specific portion, and provides a path for electrons to naturally spread in a lateral direction in a process of moving from the first surface S1 to the active layer 122 in an upper portion. Therefore, electrons do not flow only through a limited vertical path, but may be dispersed over a wide range and injected before reaching the active layer 122. That is, a spreading effect may be increased by varying a movement distance of electrons from the first conductivity type semiconductor layer 121 toward the active layer 122.

In addition, the first conductivity type semiconductor layer 121 has a structure that is spread in a transverse direction, so that regions with locally different resistances may be formed while electrons move. Accordingly, electrons may spread more efficiently within the first conductivity type semiconductor layer 121, and electrons may be evenly injected throughout the active layer 122.

Such a shape of first conductivity type semiconductor layer 121 may greatly improve current spreading, thereby allowing efficient electron-hole recombination to occur in the entire the active layer 122. Accordingly, the light emission efficiency may be improved, and a local heating phenomenon that may occur due to electrons being crowded in a specific region may be suppressed. In addition, since electrons are uniformly distributed in the active layer 122, a color difference of emitted light may be reduced, ensuring color uniformity and maintaining stable light emitting characteristics even during long-term operation.

As the first conductivity type semiconductor layer 121 has the arc cross-sectional shape, the active layer 122 covering the second surface S2 of the first conductivity type semiconductor layer 121 may also have a surface shape similar to that of the first conductivity type semiconductor layer 121.

Meanwhile, the light emitting apparatus 100 may further include a first insulation layer 150 disposed on the support layer 110 and surrounding the first conductivity type semiconductor layer 121. In this case, the active layer 122 may cover a portion of the first insulation layer 150 and the second surface S2 of the first conductivity type semiconductor layer 121.

Thicknesses n of the active layer 122 in cross-sectional view may be different at a center and an outer periphery. A thickness n of the active layer 122 at the center in cross-sectional view may be different from a thickness n of the active layer 122 at the outer periphery. For example, the thickness n of the active layer 122 may be larger at the center than at the outer periphery.

FIG. 2 is an enlarged view of the active layer 122, and each of the barrier layer 122a and the well layer 122b of the active layer 122 may have a curved shape similar to that of the second surface S2 of the first conductivity type semiconductor layer 121. The number of pairs of the multi-quantum well structure (MQW) in FIG. 2 is exemplary and the present disclosure is not limited thereto.

Due to the shape of the active layer 122 and a difference in thickness thereof between the center and the outer periphery, the well layer 122b may have different compositions in a central region including the center line C and in an outer periphery region disposed far from the center line C. For example, an indium composition at or near the center line C may be higher than an indium composition in a region disposed far from the center line C.

In other words, an indium content of the well layer 122b at the center in cross-sectional view may be different from an indium content of the well layer 122b at the outer periphery. In detail, the indium content of the well layer 122b may be higher at the center than at the outer periphery. Due to a difference in content of the well layer 122b, a color of light emitted from the active layer 122 at the center in cross-sectional view may be different from a color of light emitted from the outer periphery.

As a result, light of a wide wavelength range may be emitted from the well layer 122b. In addition, by varying current applied to the semiconductor layer 120, a color of emitted light may be varied over a wider wavelength range. A wavelength of light emitted from the well layer 122b may be white light.

Next, the second conductivity type semiconductor layer 123 covers the active layer 122, and the second conductivity type semiconductor layer 123 may have a surface shape similar to that of the active layer 122.

Accordingly, in cross-sectional view, a length of a surface of the second conductivity type semiconductor layer 123 may be longer than the length of the second surface S2.

In a case that the second conductivity type semiconductor layer 123 is a p-type semiconductor layer, it has a resistance relatively higher than that of the first conductivity type semiconductor layer 121, and a current spreading path may be expanded by increasing the length of the surface of the second conductivity type semiconductor layer 123.

In general, since the p-type semiconductor layer has low hole mobility and relatively limited current spreading, the current is likely to be crowed in a specific portion of the device. However, when the surface length of the second conductivity type semiconductor layer 123 is formed longer than the second surface S2, a contact area with the second electrode 140 in an upper portion may become larger, and a path through which the current is able to spread along a larger area may be secured. Accordingly, holes may be injected more uniformly throughout the active layer 122, and a recombination of electrons and holes may be uniformly achieved within the active layer 122, thereby improving the light emission efficiency. In addition, a local crowdedness of current density is alleviated, so that heat generation within the device becomes uniform, and as a result, a thermal stability and reliability of the device may be improved.

Furthermore, such a structure may equalize a distribution of contact resistance with the second electrode 140, thereby alleviating current imbalance in a periphery and a center of the electrode, and stabilizing a current distribution of an entire device. As a result, a variation in light emission intensity may be reduced, and uniform luminance and color characteristics may be realized on an entire light emitting surface.

In addition, thicknesses m of the second conductivity type semiconductor layer 123 in cross-sectional view may be different at a center and an outer periphery. A thickness m of the second conductivity type semiconductor layer 123 at the center in cross-sectional view may be different from a thickness m of the second conductivity type semiconductor layer 123 at the outer periphery. For example, the thickness m of the second conductivity type semiconductor layer 123 may be larger at the center than at the outer periphery.

The surface of the second conductivity type semiconductor layer 123 may have a curved shape similar to that of the second surface S2 of the first conductivity type semiconductor layer 121.

Due to the shape of the second conductivity type semiconductor layer 123 and a difference in thickness thereof between the center and the outer periphery, a composition or a concentration of a second conductive dopant in a central region including the center line C may be different from a composition or a concentration of the second conductive dopant in an outer periphery region disposed far from the center line C.

Meanwhile, the light emitting apparatus 100 may further include a second insulation layer 130 covering the second conductivity type semiconductor layer 123 and provided with an opening OP for connecting the second conductivity type semiconductor layer 123 and the second electrode 140.

The second insulation layer 130 may be formed of one or more organic or inorganic insulation materials such as a silicon oxide layer (SiO₂), a silicon nitride layer (SiNₓ), an aluminum oxide layer (Al₂O3), a titanium oxide layer (TiO₂), polyimide, or others.

The second insulation layer 130 may cover an entire second conductivity type semiconductor layer 123, and may include an opening OP that is open only in a portion of the second insulation layer 130 for electrical connection with the second electrode 140. The opening OP may be formed through a selective etching process of the second insulation layer. The opening OP exposes a portion of the surface of the second conductivity type semiconductor layer 123 so that the second electrode may be electrically connected through that region. The center line C may pass through the opening OP.

In addition, the opening OP may be formed in a single opening shape depending on the light emitting characteristics, or formed in an array structure having a plurality of fine opening patterns. When the plurality opening structure is applied, it is possible to more precisely control the current distribution and equalize the contact resistance with the electrode.

A width of the opening OP in cross-sectional view may be smaller than the cross-sectional length of the first surface S1. By limiting a size of the opening OP as mentioned above, current injected through the second electrode 140 may be induced to spread widely along the second conductivity type semiconductor layer 123 rather than being crowed in a narrow region. As a result, current spreading is improved, and it is possible to achieve uniform current injection throughout the active layer 122.

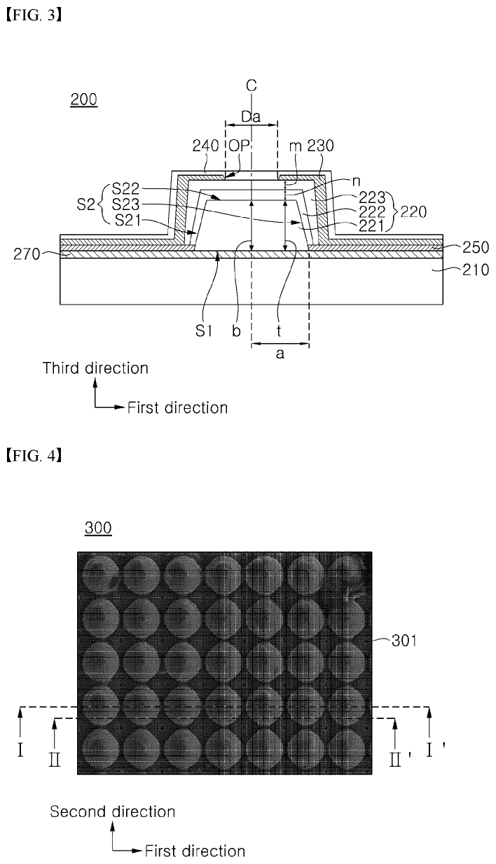

Next, FIG. 3 illustrates a light emitting apparatus 200 according to another embodiment of the present disclosure, and hereinafter, it will be described in detail focusing on differences from the light emitting apparatus 100 of FIGS. 1 and 2.

The light emitting apparatus 200 may include a semiconductor layer 220, a support layer 210, a first electrode 270, a second electrode 240, a second insulation layer 230, and a first insulation layer 250.

The light emitting apparatus 200 may have a first conductivity type semiconductor layer 221 having a trapezoidal cross-sectional shape. As the first conductivity type semiconductor layer 221 has the trapezoidal cross-sectional shape, an active layer 222 and a second conductivity type semiconductor layer 223 may also have a trapezoidal cross-sectional shape.

As with the light emitting apparatus 100 of FIG. 1, referring to FIG. 3, a cross-sectional length of a first surface S1 of the first conductivity type semiconductor layer 221 facing the first electrode 270 may be shorter than a cross-sectional length of a second surface S2 facing the active layer 222. The cross-sectional length of the second surface S2 is equal to a sum of lengths of surfaces S21 and S23 facing the active layer 222 on both sides among the surface of the first conductivity type semiconductor layer 221 and a length of a surface S22 facing the active layer 222 on an upper surface.

Since the light emitting apparatus 200 may be configured identically or similarly to the light emitting apparatus 100 of FIGS. 1 and 2 except for cross-sectional shapes of the semiconductor layer 220, the second insulation layer 230, and the second electrode 240, descriptions of overlapping configurations are omitted.

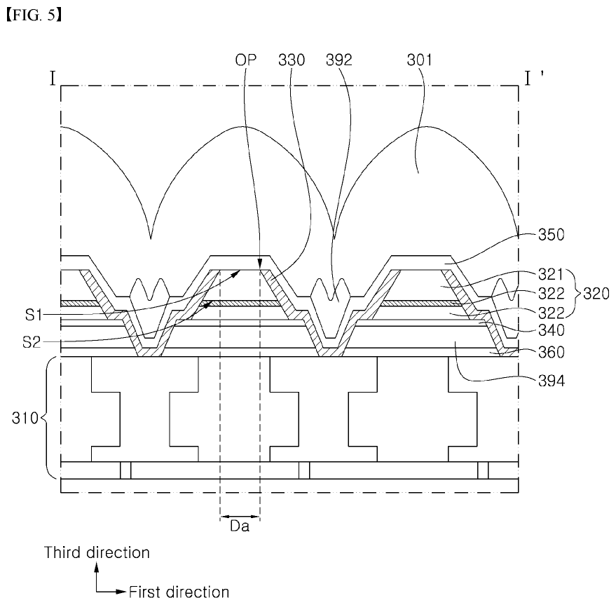

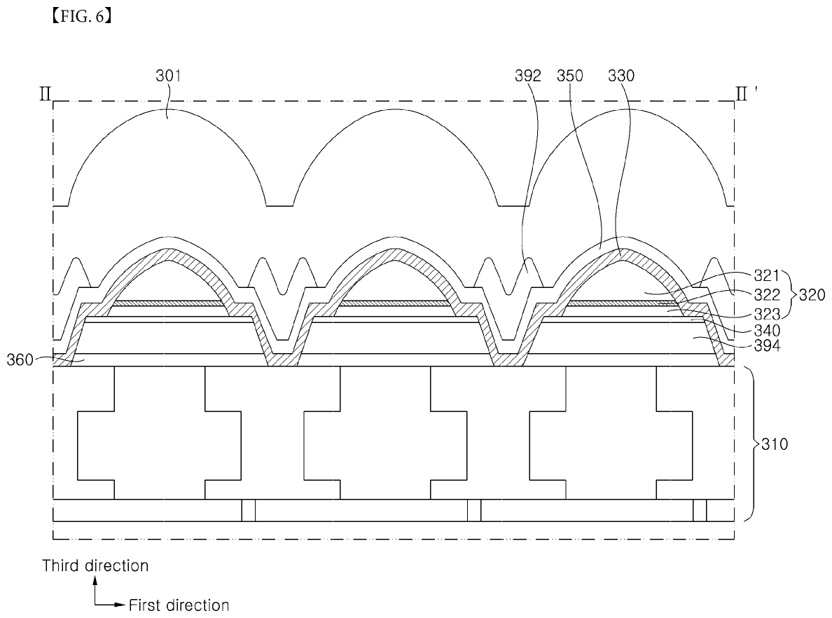

Next, FIG. 4 is a plan view illustrating a light emitting apparatus 300 according to another embodiment of the present disclosure. FIG. 5 is a cross-sectional view in a direction of I-I′ of FIG. 4, and FIG. 6 is a cross-sectional view a direction of II-II′ of FIG. 4. Hereinafter, the light emitting apparatus 300 of FIGS. 4 through 6 will be described in detail focusing on differences from the light emitting apparatuses 100 and 200 of FIGS. 1 through 3.

The light emitting apparatus 300 may include a semiconductor layer 320, a support layer 310 supporting the semiconductor layer 320, a second electrode 340 disposed between the support layer 310 and the semiconductor layer 320, and a first electrode 350 disposed on the semiconductor layer 320.

The semiconductor layer 320 may constitute one light emitting cell. The light emitting cell may be provided in a plurality and be spaced apart from one another on the support layer 310. The light emitting cell is a light emitting structure, which may be disposed in an A×B matrix pattern (A and B are natural numbers) on the support layer 310.

The support layer 310 is a substrate on which the light emitting cells are disposed and is not limited to a specific substrate. For example, the support layer 310 may include a heterogeneous substrate such as a sapphire substrate, a gallium arsenide substrate, a silicon substrate, a silicon carbide substrate, or a spinel substrate, a TFT, a circuit board, an IC substrate, and may also include a homogeneous substrate such as a gallium nitride substrate, an aluminum nitride substrate, or others. The support layer 310 may include a conductive pattern, which may be disposed over the support layer 310, disposed within the support layer 310, or pass through the support layer 310.

The semiconductor layer 320 may be formed protruding on the support layer 310. The semiconductor layer 320 may include a second conductivity type semiconductor layer 323 disposed on the second electrode 340 and electrically connected to the second electrode 340, an active layer 322 disposed on the second conductivity type semiconductor layer 323, and a first conductivity type semiconductor layer 321 disposed on the active layer 322.

Referring to FIGS. 5 and 6, the second conductivity type semiconductor layer 323, the active layer 322, and the first conductivity type semiconductor layer 321 may be sequentially disposed on the support layer 310.

The first conductivity type semiconductor layer 321 may have a form in which a width thereof is varied in a thickness direction. For example, the first conductivity type semiconductor layer 321 may have a cross-sectional width that gradually narrows as it gets far from the active layer 322. The first conductivity type semiconductor layer 321 may function as a lens that extracts light to the outside, and accordingly, light extraction efficiency may be improved.

The active layer 322 may be disposed between the first conductivity type semiconductor layer 321 and the support layer 310. Light generated in the active layer 322 may pass through the first conductivity type semiconductor layer 321 and be emitted to the outside.

The second conductivity type semiconductor layer 323 may be disposed between the active layer 322 and the support layer 310. The second conductivity type semiconductor layer 323 may have a form in which a width thereof is varied in a thickness direction. For example, the second conductivity type semiconductor layer 323 may have a shape in which the width gradually narrows as it gets close to the active layer 322.

The second conductivity type semiconductor layer 323 may be a semiconductor layer doped with a p-type dopant. The width of the second conductivity type semiconductor layer 323 in cross-sectional view may be longer than that of the first conductivity type semiconductor layer 321.

In addition, a maximum width of the second conductivity type semiconductor layer 323 may be greater than that of the first conductivity type semiconductor layer 321. In addition, a maximum thickness of the second conductivity type semiconductor layer 323 may be smaller than that of the first conductivity type semiconductor layer 321. Accordingly, a resistance of the second conductivity type semiconductor layer 323 may be lowered, thereby reducing a driving voltage and heat generation.

The first electrode 350 is an electrode disposed on the semiconductor layer 320, which may be disposed on the first conductivity type semiconductor layer 321 and electrically connected to the first conductivity type semiconductor layer 321. The first electrode 350 may be a conductive transparent electrode, and for example, it may be at least one of ITO, ZnO, or IZO. Alternatively, the first electrode 350 may be a metallic material, and may be at least one of Au, Ni, Ti, Ag, Pt, Sn, Cu, or Al.

The first electrode 350 may cover the semiconductor layer 320 and extend to the outside of the semiconductor layer 320 and cover a non-light emitting region between the semiconductor layer 320 and an adjacent semiconductor layers 320, or cover the adjacent semiconductor layer 320. Therefore, one semiconductor layer 320 and an adjacent semiconductor layer 320 may be electrically connected through the first electrode 350.

A position of a lower surface of the first electrode 350 between the one semiconductor layer 320 and the adjacent semiconductor layer 320 may be positioned lower than a position of a lower surface of the semiconductor layer 320. Accordingly, a length of the first electrode 350 becomes larger, and thus, the first electrode 350 may be prevented from being short-circuited even when the support layer 310 contracts and expands.

Meanwhile, the light emitting apparatus 300 may further include a first insulation layer 330 covering the first conductivity type semiconductor layer 321 and having an opening OP for connecting the first conductivity type semiconductor layer 321 and the first electrode 350.

The first insulation layer 330 is a layer disposed between the first electrode 350 and the semiconductor layer 320, which may cover the semiconductor layer 320 and extend outward and cover a non-light emitting region between the semiconductor layer 320 and an adjacent semiconductor layer 320, and cover the adjacent semiconductor layer 320.

The first insulation layer 330 may include the opening OP that exposes a portion of the first conductivity type semiconductor layer 321. The opening OP may be disposed at positions corresponding to each semiconductor layer 320, and the number of openings OP may be same as that of semiconductor layers 320. The first insulation layer 330 may be an insulation material such as SiO₂, TiO₂, SiNₓ, Al₂O3, or others.

In one semiconductor layer 320, a width of the opening OP in cross-sectional view may be smaller than a maximum width of the semiconductor layer 320 or a cross-sectional length of a first surface S1 of the first conductivity type semiconductor layer 321. Therefore, it is possible to prevent a generation of leakage current and increase resistance by preventing excessive electron generation.

The second electrode 340 is an electrode disposed between the support layer 310 and the semiconductor layer 320, which may be disposed under the second conductivity type semiconductor layer 323 and electrically connected to the second conductivity type semiconductor layer 323. Furthermore, the second electrode 340 may be disposed between the second conductivity type semiconductor layer 323 and a second electrode pad 394 which will be described later.

The second electrode 340 may be a conductive transparent electrode, and may be, for example, at least one of ITO, ZnO, or IZO. Alternatively, the second electrode 340 may be a metallic material, and may be at least one of Au, Ni, Ti, Ag, Pt, Sn, Cu, or Al.

A maximum width of the second electrode 340 may be greater than that of the second conductivity type semiconductor layer 323. Therefore, both ends of the second electrode 340 may extend outward from the semiconductor layer 320 and be disposed. Therefore, current spreading may be improved.

The second electrode 340 may include a same material as that of the first electrode 350.

Meanwhile, the light emitting apparatus 700 may further include a first electrode pad 392. The first electrode pad 392 is electrically connected to the first electrode 350, and may be electrically connected to the first conductivity type semiconductor layer 321. The first electrode pad 392 may be electrically connected to a plurality of semiconductor layers 320. The first electrode pad 392 may be a metallic material, and may include at least one of Au, Ni, Ti, Ag, Pt, Sn, Cu, or Al.

The first electrode pad 392 may be disposed in a non-light emitting region between the semiconductor layers 320, and may have a mesh shape in plan view. The first electrode pad 392 may surround outer peripheries of the semiconductor layers 320.

The first electrode pad 392 may include an opening exposing the semiconductor layer 320, and a minimum width of the opening may be greater than the maximum width of the semiconductor layer 320. Accordingly, a loss of emitted light may be reduced. A width of the opening of the first electrode pad 392 may be widened toward a thickness direction thereof. Therefore, a side of the opening of the first electrode pad 392 may increase the light extraction efficiency by reflecting light and guiding a path of light. A partial region of the first electrode pad 392 disposed between adjacent semiconductor layers 320 may include a concave portion concave at a central axis.

A position of a highest point of the first electrode pad 392 may be positioned higher than a position of a highest point of the semiconductor layer 320. In addition, a position of a lowest point of the first electrode pad 392 may be positioned lower than a position of a lowest point of the semiconductor layer 320. Accordingly, an emission efficiency of light emitted from a side of the semiconductor layer 320 may be increased, and optical interference between the semiconductor layers 320 may be prevented.

In addition, the light emitting apparatus 300 may further include a second electrode pad 394. The second electrode pad 394 is electrically connected to the second electrode 340, and may be electrically connected to the second conductivity type semiconductor layer 323.

The second electrode pads 394 may be provided in a plurality, and each of the second electrode pads 394 may be electrically connected to each of the semiconductor layers 320. The second electrode pad 394 may be disposed between the semiconductor layer 320 and the support layer 310, and furthermore, the second electrode pad 394 may be disposed between the second electrode 340 and the support layer 310.

The second electrode pad 394 may be a metallic material, and may include at least one of Au, Ni, Ti, Ag, Pt, Sn, Cu, or Al. In cross-sectional view, a width of the second electrode pad 394 may be gradually decreased in a thickness direction thereof. That is, a width of a lower surface of the second electrode pad 394 opposite to the support layer 310 may be larger than a width of an upper surface of the second electrode pad 394 opposite to the semiconductor layer 320. A thickness of the second electrode pad 394 may be larger than that of the second electrode 340. Accordingly, a heat capacity of the second electrode pad 394 toward a direction of a lower surface of the second electrode pad 392 may be increased, thereby increasing a heat dissipation performance.

A second insulation layer 360 may be disposed under the second electrode pad 394. A portion of the lower surface of the second electrode pad 394 may be in contact with the second insulation layer 360, and a portion of the lower surface of the second electrode pad 394 may be in contact with a conductive material. Therefore, the semiconductor layer 320 may be electrically connected to an external power source or a control apparatus such as a controller such as an IC chip, or others. The second insulation layer 360 may include an insulation material such as SiO₂, TiO₂, SiNₓ, Al₂O3, or others.

A position of the lower surface of the first electrode 350 may be positioned lower than a position of a lower surface of the second electrode 340. In addition, a position of an upper surface of the second electrode 340 may be positioned higher than the position of the lower surface of the first electrode 350. Therefore, by disposing conductive materials to be overlapped transversely, heat dissipation efficiency may be increased.

The second insulation layer 360 may extend from a lower surface of one semiconductor layer 320 to a lower surface of an adjacent semiconductor layer 320. Therefore, a bonding strength between the semiconductor layers 320 may be increased.

The light emitting apparatus 300 may further include a cover layer 301. The cover layer may be disposed over the semiconductor layer 320, and may cover the plurality of semiconductor layers 320.

The cover layer 301 may cover an upper surface of the support layer 310. In addition, the first electrode 350, the first electrode pad 392, the second electrode 340, and the second electrode pad 394 may be covered by the cover layer 301.

The first electrode 350 may be disposed between the first insulation layer 330 and the cover layer 301. Therefore, by disposing the first electrode 350 that has a relatively low refractive index between the first insulation layer 330 and the cover layer 301 that have a relatively high refractive index, total internal reflection may be reduced, thereby increasing the light extraction.

The cover layer 301 may have a shape in which a width thereof is gradually decreased toward a thickness direction, and an upper surface of the cover layer 301 may be curved. Therefore, a light refraction and light emission efficiency by the cover layer 301 may be increased.

A thickness of the cover layer 301 may be greater than that of the semiconductor layer 320. Therefore, moisture infiltration into the semiconductor layer 320 may be prevented by a thick cover layer 301.

The cover layer 301 may fill a concave portion of the first electrode pad 392. Therefore, a bonding strength between the cover layer 301 and the first electrode pad 392 may be increased, thereby preventing the cover layer 301 from falling off.

The cover layer 301 may include a plurality of protrusions formed corresponding to the plurality of semiconductor layers, respectively. A vertex of one protrusion may be disposed within an opening OP region of the first insulation layer 330 formed on a corresponding semiconductor layer 320. The protrusion may function as a lens for reflecting or refracting light emitted from the semiconductor layer in a lower portion, thereby increasing the light extraction efficiency.

As with the light emitting apparatuses 100 and 200 of FIGS. 1 through 3, the cross-sectional length of the first surface S1 of the first conductivity type semiconductor layer 321 facing the first electrode 350 may be shorter than a cross-sectional length of a second surface S2 facing the active layer 322. Since the light emitting apparatus 300 may be configured identically or similarly to the light emitting apparatuses 100 and 200 of FIGS. 1 through 3, except for a shape and an arrangement order of the semiconductor layer 320, a description of an overlapping configuration is omitted.

A light emitting module according to an embodiment of the present disclosure is not limited to a specific use such as lighting, display, or vehicle lighting, and may include one or more light emitting apparatuses 100, 200, and 300. The light emitting module may be further provided with an optical portion, a driving circuit, a heat dissipation portion, and others.

Although the present disclosure has been described above with reference to preferred embodiments, it will be understood by those skilled in the art or having ordinary knowledge in the art that various modifications and changes may be made to the present disclosure without departing from the spirit and technical scope of the present disclosure as set forth in the claims below.

Therefore, the technical scope of the present disclosure should not be limited to the contents described in the detailed description of the specification, but should be defined by the scope of the patent claims.

### DESCRIPTION OF REFERENCE NUMERALS

100, 200, 300: Light emitting apparatus
110, 210, 310: Support substrate
120, 220, 320: Semiconductor layer
121, 221, 321: First conductivity type semiconductor layer
122, 222, 322: Active layer
123, 223, 323: Second conductivity type semiconductor layer
130, 230, 360: Second insulation layer
140, 240, 350: First electrode
150, 250, 330: First insulation layer
170, 270, 340: Second electrode
301: Cover layer

1. A light emitting apparatus, comprising:
a semiconductor layer;
a support layer supporting the semiconductor layer;
a first electrode disposed between the support layer and the semiconductor layer; and
a second electrode disposed on the semiconductor layer, wherein:
the semiconductor layer includes a first conductivity type semiconductor layer disposed on the first electrode and electrically connected to the first electrode, an active layer covering the first conductivity type semiconductor layer, and a second conductivity type semiconductor layer covering the active layer and electrically connected to the second electrode, and
a cross-sectional length of a first surface facing the first electrode of the first conductivity type semiconductor layer is shorter than a cross-sectional length of a second surface facing the active layer.

2. The light emitting apparatus of claim 1, further comprising:
a second insulation layer covering the second conductivity type semiconductor layer, and provided with an opening for connecting the second conductivity type semiconductor layer and the second electrode.

3. The light emitting apparatus of claim 2,
wherein a width of the opening in a cross-sectional view is smaller than the cross-sectional length of the first surface.

4. The light emitting apparatus of claim 1, further comprising:
a first insulation layer disposed on the support layer and surrounding the first conductivity type semiconductor layer.

5. The light emitting apparatus of claim 1,
wherein a thickness of the first conductivity type semiconductor layer at a center in a cross-sectional view is different from a thickness of the first conductivity type semiconductor layer at an outer periphery.

6. The light emitting apparatus of claim 5,
wherein the thickness of the first conductivity type semiconductor layer is maximum at the center.

7. The light emitting apparatus of claim 1,
wherein the first conductivity type semiconductor layer has an arc cross-sectional shape.

8. The light emitting apparatus of claim 1,
wherein an angle formed by two line segments connecting a vertex of the first conductivity type semiconductor layer and each of two edges in a lower portion of the first conductivity type semiconductor layer in a cross-sectional view is an obtuse angle.

9. The light emitting apparatus of claim 1,
wherein a vertical length of the first conductivity type semiconductor layer from a center in a lower portion of the first conductivity type semiconductor layer in a cross-sectional view is shorter than a length from the center in the lower portion to an edge in the lower portion.

10. The light emitting apparatus of claim 1,
wherein a length of a surface of the second conductivity type semiconductor layer in a cross-sectional view is longer than a length of the second surface.

11. The light emitting apparatus of claim 1,
wherein a thickness of the second conductivity type semiconductor layer at a center in a cross-sectional view is different from a thickness of the second conductivity type semiconductor layer at an outer periphery.

12. The light emitting apparatus of claim 1,
wherein a thickness of the active layer at a center in a cross-sectional view is different from a thickness of the active layer at an outer periphery.

13. The light emitting apparatus of claim 1, wherein:
the active layer includes a multi-quantum well structure (MQW) including a plurality of barrier layers and a plurality of well layers, and
an indium content of a well layer of the plurality of well layers at a center in a cross-sectional view is different from an indium content of a well layer of the plurality of well layers at an outer periphery.

14. The light emitting apparatus of claim 1,
wherein a color of light emitted from the active layer at a center in a cross-sectional view is different from a color of light emitted from an outer periphery.

15. The light emitting apparatus of claim 1,
wherein the first conductivity type semiconductor layer has a trapezoidal cross-sectional shape.

16. A light emitting apparatus, comprising:
a semiconductor layer;
a support layer supporting the semiconductor layer:
a second electrode disposed between the support layer and the semiconductor layer; and
a first electrode disposed on the semiconductor layer, wherein:
the semiconductor layer includes a second conductivity type semiconductor layer disposed on the second electrode and electrically connected to the second electrode, an active layer disposed on the second conductivity type semiconductor layer, and a first conductivity type semiconductor layer disposed on the active layer, and
a cross-sectional length of a first surface facing the first electrode of the first conductivity type semiconductor layer is shorter than a cross-sectional length of a second surface facing the active layer.

17. The light emitting apparatus of claim 16, further comprising:
a first insulation layer covering the first conductivity type semiconductor layer and provided with an opening for connecting the first conductivity type semiconductor layer and the first electrode.

18. The light emitting apparatus of claim 16, wherein:
the second conductivity type semiconductor layer is a semiconductor layer doped with a p-type dopant, and
a width of the second conductivity type semiconductor layer in a cross-sectional view is longer than a width of the first conductivity type semiconductor layer.

19. The light emitting apparatus of claim 16,
wherein a width of the first conductivity type semiconductor layer in a cross-sectional view decreases in a direction away from the active layer.

20. The light emitting apparatus of claim 16,
wherein the semiconductor layer is provided in a plurality of semiconductor layers, each of the plurality of semiconductor layers being spaced apart from one another in a plan view, and
the light emitting apparatus further comprises a cover layer covering the plurality of semiconductor layers.
